(19) United States
(12) Patent Application Publication
(10) Pub. No.: US 2009/0315130 A1
(43) Pub. Date: Dec. 24, 2009

(54) Solid-state imaging apparatus and method for manufacturing the same

(76) Inventors: Young-Hoon Ro, Chungcheongnam-do (KR); Young-Shin Kwon, Gyeonggi-do (KR); Seung-Kon Mok, Gyeonggi-do (KR)

Correspondence Address: HARNESS, DICKEY & PIERCE, P.L.C., P.O. BOX 8910, RESTON, VA, 20195, US

(21) Appl. No.: 10/915,334

(22) Filed: Aug. 11, 2004

(30) Foreign Application Priority Data
Aug. 12, 2003 (KR) 10-2003-0055786

(51) Int. Cl. H01L 31/0232; H01L 31/18

(52) U.S. Cl. 257/432; 438/65; 257/E31.127; 257/E21.502

(57) ABSTRACT

A solid-state imaging apparatus and method for manufacturing the imaging apparatus. A solid-state imaging apparatus with reduced thickness and/or mounting area by forming an aperture in a board and placing a solid-state semiconductor imaging chip, an image processing semiconductor chip, and/or a combination imaging/processing chip within the aperture.

### CROSS-REFERENCE TO RELATED APPLICATIONS

This application claims priority of Korean Patent Application No. 10-2003-0055786 filed on Aug. 12, 2003 in the Korean Intellectual Property Office, the disclosure of which is incorporated herein in its entirety by reference.

### FIELD OF THE INVENTION

The present invention relates to a solid-state imaging apparatus and method for manufacturing the same. More particularly, the present invention relates to a package module for a solid-state imaging apparatus and a method for manufacturing the same, in which a semiconductor device, capable of holding a light-receiving element, and a solid-state imaging lens may be integrated.

### DESCRIPTION OF THE CONVENTIONAL ART

Conventional camera modules may utilize a solid-state imaging semiconductor chip and a lens which may be mounted on mobile apparatuses such as a mobile terminal or phone. A mobile phone may allow a caller to capture an image in the form of image data through a small camera and to transmit the image data to the receiver.

As mobile phones and portable personal computers (“portable PCs”) become more compact, there may also be a need to reduce the size of the camera module which may be used in the mobile phone or portable PC.

Referring to FIG. 1, a camera module which may include a lens unit 180, in which a solid-state imaging lens 160 and an IR cut filter 170 may be installed, may be bonded to a portion of the top surface of a board 100 with an adhesive. A solid-state imaging semiconductor chip 110 may comprise a group of photoelectric conversion elements which may convert light from the solid-state imaging lens 160 into an image signal. The solid-state imaging semiconductor chip 110 may be positioned on the board 100 and may be wire-bonded to a substrate pad which may be formed at a portion of the top surface of the board 100 (see 120).

An image processing semiconductor chip 130 may be wire-bonded to a substrate pad which may be formed at a portion of the bottom surface of the board 100 (see 140). The image processing semiconductor chip 130 may be sealed using an insulating sealing resin 150 which may be fabricated by a transfer mold technique. The image processing semiconductor chip 130 may process the image signal from the solid-state imaging semiconductor chip 110.

The board 100 and a flexible cable 190 may be electrically connected to each other by means of a cable junction 185. The solid-state imaging semiconductor chip 110 and the image processing semiconductor chip 130 may be bonded to the top and bottom surfaces of the board 100 and may be electrically connected thereto through bonding wires 120 and 140, and the solid-state imaging apparatus may be manufactured easier and the assembling costs may be reduced. The image processing semiconductor chip 130 and the insulating sealing resin 150 which may be formed below the board 100, may cause the camera module to become thicker.

### SUMMARY OF THE INVENTION

Exemplary embodiments of the present invention may provide a thinner, more compact and reduced priced solid-state imaging apparatus and a method for manufacturing the same.

Exemplary embodiments of the present invention may provide a solid-state imaging apparatus, which may comprise a lens unit capable of holding a solid-state imaging lens, a board which may be bonded, directly or indirectly, to the bottom of the lens unit and may be formed with an aperture at a portion thereof, and a solid-state semiconductor chip which may be positioned below the solid-state imaging lens and may be electrically connected to the board through a first electrical connection, which may be wire bonding, and may convert light from the solid-state imaging lens into an image signal.

Exemplary embodiments of the present invention may comprise a solid state semiconductor chip which may be positioned within, above, or below the aperture of the board and may be electrically connected to the board through a second electrical connection, which may be wire bonding, and may be sealed with an insulating sealing resin.

Exemplary embodiments of the of the present invention may further comprise an infrared cut filter that may face the solid-state imaging lens at an interval, may be disposed between the solid-state imaging lens and the board, and may be installed in the lens unit.

In an exemplary embodiment of the present invention, there may be provided a solid-state imaging apparatus, which may comprise a lens unit capable of holding a solid-state imaging lens and a board which may be bonded, directly or indirectly, to the bottom of the lens unit and may be formed with an aperture at a position below the solid-state imaging lens. A thin film tape, which may be made of polyimide and may be transparent, may cover a bottom face, a top face, or be positioned within the aperture. A solid-state semiconductor chip may be positioned above, below, or within the aperture of the board by directly or indirectly bonding to the board, and may be electrically connected to a substrate pad of the board through a third electrical connection, which may be wire bonding.

An exemplary embodiment may comprise an infrared cut filter that may face the solid-state imaging lens at an interval, may be disposed between the solid-state imaging lens and the board, and may be installed in the lens unit. The thin film tape may be made of polyimide, and the solid state semiconductor chip may be an imaging chip, a processing chip, or an imaging/processing chip.

In another exemplary embodiment of the present invention, a method for manufacturing a solid-state imaging apparatus may be provided. The apparatus may comprise forming an aperture in a portion of a board and covering a top face or a bottom face of the aperture with a thin film tape, or positioning the thin film tape within the aperture. An image processing semiconductor chip may be positioned above, below, or in the aperture by bonding the image processing semiconductor chip, directly or indirectly, to adhesive material from the thin film tape and electrically connecting the image processing semiconductor chip and the board directly or indirectly through a second electrical connection. A lens unit, which may be capable of holding a solid-state imaging lens at a position above the solid-state imaging semiconductor chip, may be bonded to the top surface of the board. A solid-state imaging semiconductor chip may be bonded, directly or indirectly, to a top surface of the board and electrically connected to the board through a first electrical connection. The second electrical connection may be wire bonding.

Exemplary embodiments of the method for manufacturing the solid-state imaging apparatus of the present invention may further comprise sealing the image processing semiconductor chip and the board with an insulating sealing resin, and removing the thin film tape to leave adhesive material behind.

An infrared cut filter, which may face the solid-state imaging lens at an interval and may be disposed between the solid-state imaging lens and the board, may be installed in the lens unit. The first electrical connection may be wire bonding, a solder ball, or metal bump.

In another exemplary embodiment of the present invention, there may be provided a method for manufacturing a solid-state imaging apparatus, which may comprise forming an aperture in a portion of a board; covering a bottom face or a top face, of the aperture with a thin film tape, or positioning a thin film tape within the aperture; positioning a solid-state imaging semiconductor chip on the top face, bottom face, or within the aperture by bonding the solid-state imaging semiconductor chip, directly or indirectly, to adhesive material from the thin film tape and electrically connecting the solid-state imaging semiconductor chip and the board through a third electrical connection. A lens unit, capable of holding a solid-state imaging lens, at a position above the solid-state imaging semiconductor chip, may be bonded to a top surface of the board.

In an exemplary embodiment, the third electrical connection may be wire bonding.

An exemplary embodiment of the present invention may comprise installing an infrared cut filter into the lens unit, which may face the solid-state imaging lens at an interval and may be disposed between the solid-state imaging lens and the board.

In an exemplary embodiment, the thin film tape may be made of polyimide.

### BRIEF DESCRIPTION OF THE DRAWINGS

The above and other objects, features and advantages of the present invention will become apparent from the following description of exemplary embodiments given in conjunction with the accompanying drawings, in which:

FIG. 1 schematically illustrates the construction of a conventional solid-state imaging apparatus;

FIGS. 2a to 2d schematically illustrate the processes of manufacturing a solid-state imaging apparatus according to an exemplary embodiment of the present invention;

FIGS. 3a to 3d schematically illustrate the processes of manufacturing a solid-state imaging apparatus according to another exemplary embodiment of the present invention; and

FIGS. 4a to 4c schematically illustrate the processes of manufacturing a solid-state imaging apparatus according to another exemplary embodiment of the present invention.

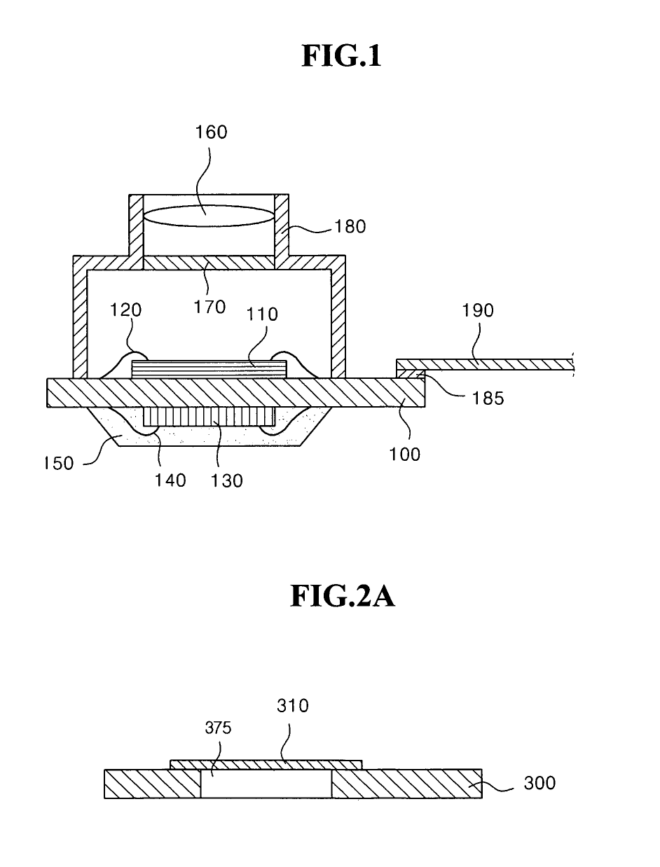

### DETAILED DESCRIPTION OF THE EXEMPLARY EMBODIMENTS

Exemplary embodiments of the present invention will be described in detail with reference to the accompanying drawings such that those of ordinary skill in the art may more easily embody the present invention.

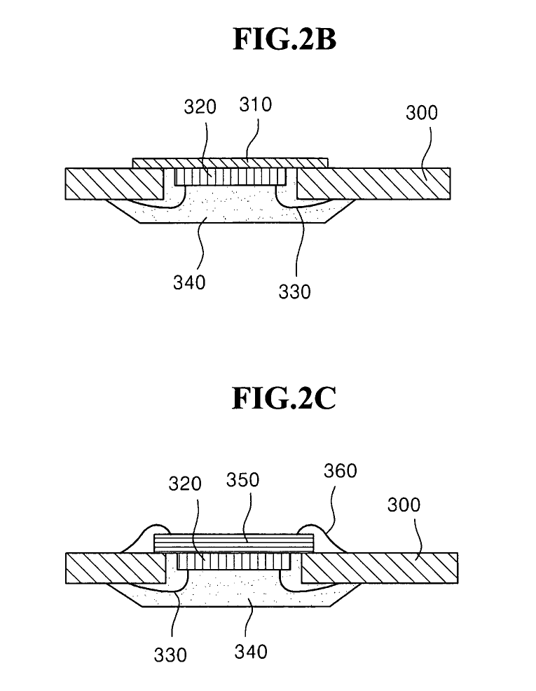

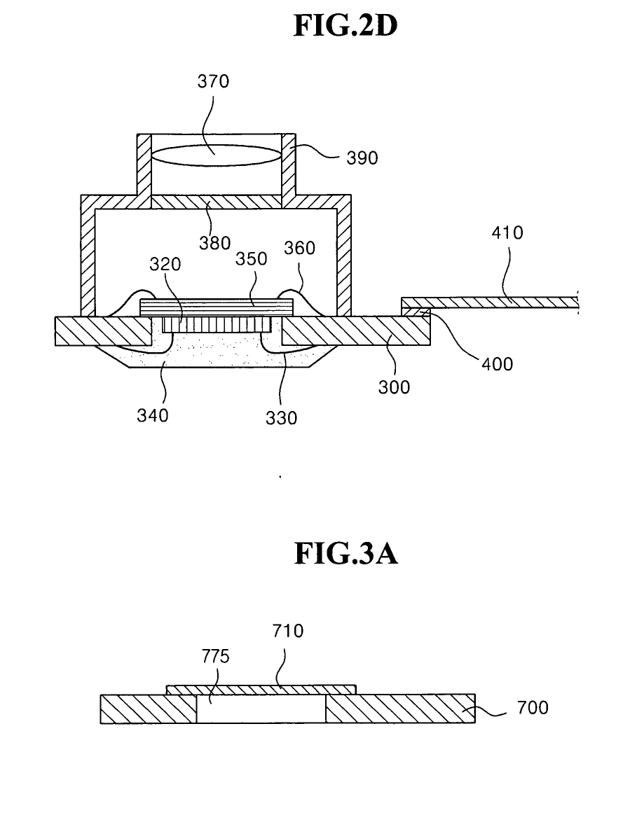

Referring to FIG. 2a, an aperture 375 may be formed at a portion of a board 300 (for example, a printed circuit board (PCB) or a flexible PCB), and wirings may be formed on the top and bottom surfaces of the board 300. The top face of the aperture 375 may be covered with a thin film tape 310. The thin film tape 310 may be coated with an adhesive material, which may be made of a material that may be stable at higher temperatures, and may be made of polyimide.

As shown in FIG. 2b, an image processing semiconductor chip 320 may be positioned in the aperture 375 and the thin film tape 310 may be bonded, directly or indirectly, to a surface thereof. A chip pad, which may be formed on the bottom surface of the image processing semiconductor chip 320, and a substrate pad, which may be formed on the bottom surface of the board 300, may be electrically connected, directly or indirectly, to each other through a second electrical connection 330. The second electrical connection 330 may be a bonding wire.

The image processing semiconductor chip 320 may be sealed with an insulating sealing resin 340. The insulating sealing resin 340 may improve the reliability of, and strengthen the electrically bonded portion. The insulating sealing resin 340 may comprise an insulating epoxy resin, an insulating silicon resin and the like and the insulating sealing resin 340 may secure the image processing semiconductor chip 320 to the board 300.

A molding process, a dispensing process and the like may be used as the sealing process.

The molding process may refer to a process of enveloping the semiconductor in a form which may protect the chips, wires, inner leads, etc. of the semiconductor from external charges and shock. The molding process may include mounting a lead frame and a substrate on a mold die that may be engraved to have a specific shape. The mold die may be filled with a viscous material by applying heat, pressure, and curing the viscous material.

The dispensing process may be a method for discharging a solution around a structural chip which may be capable of dispensing the solution such that the bottom of the chip may be filled with the solution. The solution may be a low viscosity solution. The dispensing process may be significantly different from the molding process in that the former may not use a mold die. As a dispensing method, there may be a damming process, a filling process and the like. The damming process may include defining a line on an outer edge of a portion to be dispensed using a liquid sealing material. The filling process may include filling the liquid sealing material into an inner side which may be formed by the damming process.

The thermosetting and insulating sealing resin 340 may be cured, and the thin film tape 310 may be removed. As shown in FIG. 2c, a solid-state imaging semiconductor chip 350 may be bonded, directly or indirectly, to the surface of the image processing semiconductor chip 320 from which the thin film tape 310 may be removed. An epoxy resin adhesive containing silver (Ag) may be used for the bonding. The solid-state imaging semiconductor chip 350 may also be bonded, directly or indirectly, to the side of the thin film tape 310 without removing the thin film tape. A chip pad, which may be formed on the top surface of the solid-state imaging semiconductor chip 350, and a substrate pad, which may be formed on the top surface of the board 300, may be electrically connected to each other via a first electrical connection 360. The first electrical connection 360 may be a bonding wire.

The solid-state imaging semiconductor chip 350 may be a chip which may include a group of photoelectric conversion elements which may convert light from a solid-state imaging lens 370 (shown in FIG. 2d) into an image signal. The solid-state imaging semiconductor chip 350 may comprise a photoelectric conversion unit (sensor unit), which may include a group of the two-dimensionally arranged photoelectric conversion elements constituting a CMOS image sensor (CIS), a driving circuit unit which may sequentially drive the group of the photoelectric conversion elements and may be used to obtain a signal charge, an A/D conversion unit which may convert the signal charge into a digital signal, a signal processing unit which may process the digital signal into an image signal output, and a semiconductor circuit unit in which an exposure control unit electrically controlling exposure time based on the output level of the digital signal may be used. The solid-state imaging semiconductor chip 350 may also include a CCD (charged coupled device).

As shown in FIG. 2d, a lens unit 390, which may include a solid-state imaging lens 370, may be fixed to a portion on the board 300 using an adhesive. The solid-state imaging lens 370 may be positioned above the solid-state imaging semiconductor chip 350.

An IR cut filter 380 or high frequency cutoff filter may be provided within the lens unit 390 such that it may face the solid-state imaging lens 370 and may be located where the light from the solid-state imaging lens 370 may travel. The solid-state imaging apparatus may be operated in such a manner that an object image may be captured on the sensor unit in the solid-state imaging semiconductor chip 350 through the solid-state imaging lens 370 and the IR cut filter 380 and may be photo-electrically converted such that digital or analog image signals may be output. The image processing semiconductor chip 320 may be electrically connected to a surface of the board 300 through the second electrical connection 330 and may process the image signal from the solid-state imaging semiconductor chip 350.

The board 300 may be electrically connected to a flexible cable 410 through a cable junction 400, such that the solid-state imaging apparatus may be connected to an external system.

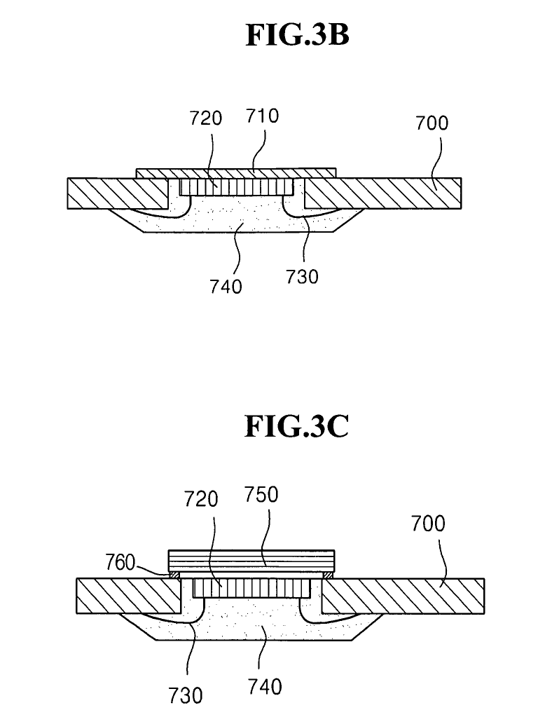

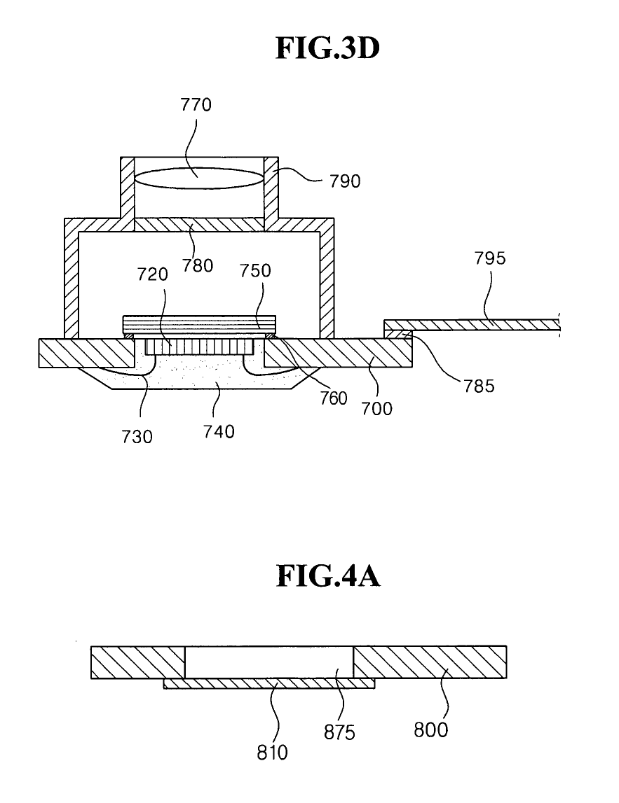

In another exemplary embodiment of the present invention, referring to FIG. 3a, an aperture 775 may be formed at a portion in a board 700 (for example, a printed circuit board (PCB) or a flexible PCB), and wirings may be formed on the top and bottom surfaces of the board 700. The top face of the aperture 775 may be covered with a thin film tape 710, which may be coated with an adhesive material, and may be made of a material that may be stable even at higher temperatures. The thin film tape may be made of polyimide.

As shown in FIG. 3b, an image processing semiconductor chip 720 may be positioned in the aperture 775 and the thin film tape 710 may be bonded, directly or indirectly, to one or more surfaces thereof. A chip pad, which may be formed on the bottom surface of the image processing semiconductor chip 720, and a substrate pad, which may be formed on the bottom surface of the board 700, may be electrically connected to each other through another second electrical connection 730. The second electrical connection 730 may be bonding wire.

The image processing semiconductor chip 720 may be sealed with an insulating sealing resin 740. The insulating sealing resin 740 may improve the reliability of and strengthen the electrically bonded portion. The insulating sealing resin 740 may comprise an insulating epoxy resin, an insulating silicon resin and the like.

The thermosetting and insulating sealing resin 740 may be cured, and the thin film tape 710 may be removed. As shown in FIG. 3c, a solid-state imaging semiconductor chip 750 may be bonded, directly or indirectly, to the surface of the image processing semiconductor chip 720 from which the thin film tape 710 may be removed. An epoxy resin adhesive containing silver (Ag) may be used for the bonding. The solid-state imaging semiconductor chip 750 may be bonded, directly or indirectly, to the side of the thin film tape 710 without removing the thin film tape 710.

A chip pad, which may be formed on the top surface of the solid-state imaging semiconductor chip 350, and a substrate pad, which may be formed on the top surface of the board 300, may be electrically connected to each other via a first electrical connection 360. The first electrical connection 360 may be a bonding wire.

A chip pad, which may be formed on the top surface of the solid-state imaging semiconductor chip 750, may be electrically connected to a terminal which may be formed on the bottom surface of the solid-state imaging semiconductor chip 750. The chip pad and the terminal may be electrically connected to each other by a via hole which may be formed in the chip pad of the solid-state imaging semiconductor chip 750, which may use an etching technique of forming a conductive line along the lateral sides of the solid-state imaging semiconductor chip 750. The method of forming the via hole and connecting the via hole and the board is disclosed in U.S. Pat. No. 6,235,554 and Korean Patent Laid-Open Publication No. 2003-0023040. The method of forming the conductive line and connecting the conductive line and the board is disclosed in U.S. Pat. No. 6,391,685, Korean Patent Laid-Open Publication Nos. 2001-0001159 and 2001-0018694.

The terminal, which may be formed on the bottom surface of the solid-state imaging semiconductor chip 750, and the substrate pad, which may be formed on the top surface of the board 700, may be electrically connected to each other through another first electrical connection 760. The first electrical connection 760 may be a solder ball or metal bump.

As shown in FIG. 3d, a lens unit 790, capable of holding a solid-state imaging lens 770, may be fixed to a portion of the board 700 using an adhesive. The solid-state imaging lens 770 may be positioned above the solid-state imaging semiconductor chip 750.

An IR cut filter 780 or high frequency cutoff filter may be provided within the lens unit 790 such that it may face the solid-state imaging lens 770 and may be located where the light from the solid-state imaging lens 770 travels.

The solid-state imaging apparatus may be operated in such a manner that an image may be captured on the sensor unit in the solid-state imaging semiconductor chip 750 through the solid-state imaging lens 770 and the IR cut filter 780 and may be photo-electrically converted such that digital or analog image signals may be output. The image processing semiconductor chip 720 may be electrically connected to the bottom surface of the board 700 through the second electrical connection 730, and may process the image signal from the solid-state imaging semiconductor chip 750.

The board 700 may be electrically connected to a flexible cable 795 through a cable junction 785, such that the solid-state imaging apparatus may be connected to an external system.

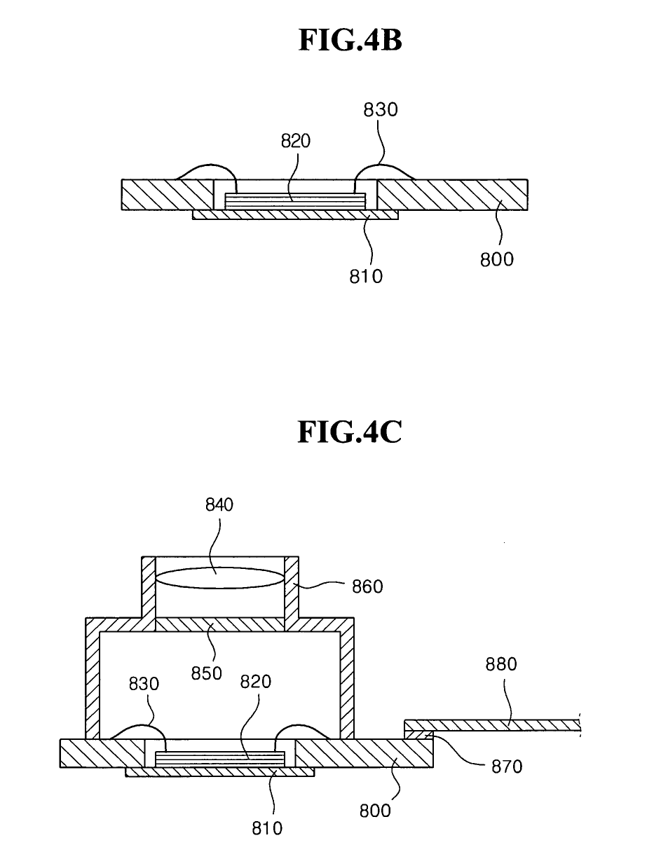

In another exemplary embodiment of the present invention, referring to FIG. 4a, an aperture 875 may be formed in a portion of a board 800 (for example, a printed circuit board (PCB) or a flexible PCB). The bottom face of the aperture 875 may be covered with a thin film tape 810. The thin film tape 810 may be coated with an adhesive material, may be made of a material that may be stable at higher temperatures, and may be made of polyimide.

As shown in FIG. 4b, a solid-state imaging semiconductor chip 820 may be positioned in the aperture 875 and the thin film tape 810 may be bonded, directly or indirectly, to one or more surfaces thereof. An insulating sealing resin may be coated around the solid-state imaging semiconductor chip 820 within the aperture 875 of the board 800.

The thin film tape 810 may be 0.05 to 0.2 mm in thickness and may be fixed, directly or indirectly, to the solid-state imaging semiconductor chip 820. The solid-state imaging semiconductor chip 820 may include an image processing semiconductor chip. A chip pad, which may be formed on the top surface of the solid-state imaging semiconductor chip 350, and a substrate pad, which may be formed on the top surface of the board 300, may be electrically connected, directly or indirectly, to each other via a first electrical connection 360. The first electrical connection 360 may be bonding wire. A chip pad, which may be formed on the top surface of the solid-state imaging semiconductor chip 820, and a substrate pad, which may be formed on the top surface of the board 800, may be electrically connected to each other, directly or indirectly, by a third electrical connection 830. The third electrical connection 830 may be bonding wire.

As shown in FIG. 4c, a lens unit 860 which may include a solid-state imaging lens 840, may be fixed directly or indirectly to a portion of the board 800 using an adhesive. The solid-state imaging lens 840 may be positioned above the solid-state imaging semiconductor chip 820.

An IR cut filter 850 or high frequency cutoff filter may be provided within the lens unit 860 such that it may face the solid-state imaging lens 840 and may be located where the light from the solid-state imaging lens 840 may travel.

The board 800 may be electrically connected to a flexible cable 880 through a cable junction 870, such that the solid-state imaging apparatus may be connected to an external system.

According to the exemplary embodiments of the present invention described above, an aperture may be formed in a board and a solid-state semiconductor imaging chip, an image processing semiconductor chip, both a solid-state semiconductor imaging chip and an image processing semiconductor chip, or an imaging/processing semiconductor chip may be installed within the aperture, and may provide a solid-state imaging apparatus with reduced thickness and mounting area.

Although the thin film tape or other adhesive, according to exemplary embodiments of the present invention, may cover a top face or a bottom face of the aperture at a portion of the board, it will be understood that the thin film tape may cover a top face, a bottom face or be positioned within the aperture of the board, as desired by one of ordinary skill in the art.

Although the solid-state semiconductor imaging chip and the image processing semiconductor chip, according to exemplary embodiments of the present invention, may be positioned within the aperture of the board, it will be understood that any of the solid-state semiconductor imaging chip, the image processing semiconductor chip, and/or an imaging/processing semiconductor chip, may be positioned either alone or in combination within the aperture of the board as desired by one of ordinary skill in the art. It will further be understood that any variation of the positioning of the semiconductor chip may be combined with any variation of the positioning of the thin film tape or other adhesive material, as desired by one of ordinary skill in the art.

Although the thin film tape or other adhesive material, according to exemplary embodiments of the present invention, may cover any face of the solid-state semiconductor imaging chip, the image processing semiconductor chip, and/or an imaging/processing semiconductor chip, it will be appreciated that the thin film tape or other adhesive material may be selected and/or located so as not to interfere with the optical functions of the solid-state imaging apparatus.

Although the adhesive material, according to exemplary embodiments of the present invention, may be adhesive residue from a thin film tape, which may be polyimide, it will be understood that the adhesive material may be any similar, or substantially similar, adhesive material (for example, other adhesive materials, including transparent adhesive materials), as desired by one of ordinary skill in the art. Although in an exemplary method for manufacturing a solid-state imaging apparatus, the solid-state imaging semiconductor chip is secured before the lens unit is bonded, as desired by one of ordinary skill in the art, the lens unit may be bonded before the solid-state imaging semiconductor chip is secured, as desired by one of ordinary skill in the art.

Although the present invention has been described in connection with the exemplary embodiments thereof, it is not limited thereto. It may be apparent to those of ordinary skill in the art that various substitutions, modifications and changes may be made thereto without departing from the scope and spirit of the invention.

What is claimed is:

1. A solid state imaging apparatus comprising:
a lens unit capable of holding a solid-state imaging lens;
a board bonded to the lens unit and formed with an aperture therein; and
at least one solid state semiconductor chip secured to the board;
wherein the at least one solid state semiconductor chip is positioned within the aperture.

2. The apparatus of claim 1, wherein the at least one solid state semiconductor chip is an imaging/processing chip.

3. The apparatus of claim 2, wherein
the imaging/processing chip is electrically connected to the board by a third electrical connection.

4. The apparatus of claim 3, wherein the third electrical connection is wire bonding.

5. The apparatus of claim 2, wherein a thin film tape is positioned below the imaging/processing chip to secure the imaging/processing chip to the board.

6. The apparatus of claim 2, wherein a thin film tape is positioned below the imaging/processing chip to temporarily secure the imaging/processing chip to the board.

7. The apparatus of claim 2, wherein a thin film tape is positioned above the imaging/processing chip to secure the imaging/processing chip to the board.

8. The apparatus of claim 7, further comprising an epoxy resin for securing the imaging/processing chip to another imaging/processing chip.

9. The apparatus of claim 8, wherein the thin film tape and the epoxy resin are transparent.

10. The apparatus of claim 2, wherein a thin film tape is positioned above the imaging/processing chip to temporarily secure the imaging/processing chip to the board.

11. The apparatus of claim 10, further comprising an epoxy resin for securing the imaging/processing chip to another imaging/processing chip after the thin film tape is removed.

12. The apparatus of claim 11, wherein the epoxy resin is transparent.

13. The apparatus of claim 2, wherein the imaging/processing chip and an adhesive material for securing the imaging/processing chip to the board are positioned in said aperture.

14. The apparatus of claim 1, wherein the at least one solid state semiconductor chip includes at least two chips including an imaging chip and a processing chip.

15. The apparatus of claim 14, wherein
the imaging chip is electrically connected to the board by a first electrical connection; and
the processing chip is electrically connected to the board by a second electrical connection.

16. The apparatus of claim 15, wherein
the first electrical connection is one of wire bonding, a solder ball, or a metal bump; and
the second electrical connection is wire bonding.

17. The apparatus of claim 16, wherein
the second electrical connection is sealed with an insulating sealing resin.

18. The apparatus of claim 1, further comprising:
an infrared cut filter in the lens unit between the solid state imaging lens and the board.

19. A method for manufacturing a solid state imaging apparatus comprising:
securing at least one solid state semiconductor chip to a board with an aperture therein; and
bonding a lens unit capable of holding a solid-state imaging lens to the board;
wherein the at least one solid state semiconductor chip is positioned within the aperture.

20. The method of claim 19, wherein the at least one solid state semiconductor chip is an imaging/processing chip.

21. The method of claim 20, further comprising electrically connecting the imaging/processing chip to the board by a third electrical connection.

22. The method of claim 21, wherein the third electrical connection is wire bonding.

23. The method of claim 20, further comprising providing a thin film tape below the imaging/processing chip to secure the imaging/processing chip to the board.

24. The method of claim 20, further comprising temporarily providing a thin film tape below the imaging/processing chip to secure the imaging/processing chip to the board.

25. The method of claim 20, further comprising providing a thin film tape above the imaging/processing chip to secure the imaging/processing chip to the board.

26. The method of claim 25, further comprising providing an epoxy resin for securing the imaging/processing chip to another imaging/processing chip.

27. The method of claim 26, wherein the thin film tape and the epoxy resin are transparent.

28. The method of claim 20, further comprising temporarily providing a thin film tape above the imaging/processing chip to secure the imaging/processing chip to the board.

29. The method of claim 28, further comprising providing an epoxy resin for securing the imaging/processing chip to another imaging/processing chip after the thin film tape is removed.

30. The method of claim 29, wherein the epoxy resin is transparent.

31. The method of claim 20, further comprising positioning the imaging/processing chip and an adhesive material for securing the imaging/processing chip to the board in said aperture.

32. The method of claim 19, wherein the at least one solid state semiconductor chip includes at least two chips including an imaging chip and a processing chip.

33. The method of claim 32, wherein
the imaging chip is electrically connected to the board by a first electrical connection; and
the processing chip is electrically connected to the board by a second electrical connection.

34. The method of claim 33, wherein
the first electrical connection is one of wire bonding, a solder ball, or a metal bump; and
the second electrical connection is wire bonding.

35. The method of claim 34, wherein
the second electrical connection is sealed with an insulating sealing resin.

36. The method of claim 19, further comprising:
positioning an infrared cut filter in the lens unit between the solid state imaging lens and the board.

37. The apparatus of claim 14, wherein, the processing chip is positioned in said aperture and the imaging chip is positioned above the processing chip.

38. The apparatus of claim 37, wherein a thin film tape is positioned above the processing chip to temporarily secure the processing chip to the board.

39. The apparatus of claim 38, further comprising a sealing resin for securing the processing chip to the board after the thin film tape is removed.

40. The method of claim 32, further comprising:
positioning the processing chip in said aperture; and
positioning the imaging chip above the processing chip.

41. The method of claim 40, further comprising temporarily providing a thin film tape above the processing chip to secure the processing chip to the board.

42. The method of claim 41, further comprising providing a sealing resin for securing the processing chip to the board after the thin film tape is removed.
